(19) United States
(12) Patent Application Publication
(10) Pub. No.: US 2025/0279778 A1
(43) Pub. Date: Sep. 4, 2025

(54) SAFETY DISCONNECT CIRCUIT WITH AUTOMATIC RETRY

(71) Applicant: Texas Instruments Incorporated, Dallas, TX (US)

(72) Inventors: Hakan Oner, SAN JOSE, CA (US); Ankit Gupta, SUNNYVALE, CA (US); Marc Davis-Marsh, SAN JOSE, CA (US)

(21) Appl. No.: 18/676,844

(22) Filed: May 29, 2024

Related U.S. Application Data
(60) Provisional application No. 63/559,510, filed on Feb. 29, 2024.

(51) Int. Cl. H03K 17/0812; H03K 17/30; H03K 19/00; H03K 19/173

(52) U.S. Cl. CPC H03K 17/08126; H03K 17/30; H03K 19/0016; H03K 19/1737

(57) ABSTRACT

Described embodiments include a safety disconnect circuit having a logic circuit with first, second and third logic inputs and a logic output. A latch has a latch input coupled to the logic output, a latch power input, and a latch output. A counter has a counter input coupled to the logic output, and a counter output. A switch is coupled between a fault terminal and a ground terminal, and has a switch control terminal coupled to the latch output. A first voltage supply has a first supply input and a first supply output. A second voltage supply has a second supply input and a second supply output. A multiplexer has first and second multiplexer inputs that are coupled to first and second supply outputs, respectively. The multiplexer output is coupled to the latch power input. The multiplexer control terminal is coupled to the counter output.

### CROSS-REFERENCE TO RELATED APPLICATION

This application claims priority to U.S. Provisional Patent Application No. 63/559,510 filed Feb. 29, 2024, which is incorporated herein by reference in its entirety.

### BACKGROUND

This description relates to safety disconnect circuits. Safety disconnect circuits are sometimes included in DC-DC voltage converter circuits. Safety-critical systems may require provisions for a safety disconnect in the event of a catastrophic fault within the system. A safety-critical system is a system that needs to function properly in order to avoid a worst-case scenario, such as human injury and/or death, significant property damage, financial loss, environmental damage, or a catastrophic systemic effect. Examples of a safety-critical system include automobiles having autonomous driving control, motor control systems in factories, and anywhere a person could potentially get seriously injured by high voltage.

One example of a system implementing a safety disconnect circuit is a buck DC-DC voltage converter. A potential failure mode in a buck DC-DC voltage converter is a short circuit in the high side drive FET, which can potentially apply a high voltage directly on the output voltage terminal of the DC-DC voltage converter. If this occurs, it can cause damage to downstream equipment connected to the voltage regulator, which can lead to further failures.

A safety disconnect circuit usually includes a safety mechanism that detects the failure, then takes the appropriate actions to protect the system and its users. In the case of a DC-DC voltage converter, the appropriate action may be to disconnect and latch off power to the system until the failure can be remedied. If the safety disconnect circuit is in an automobile, the owner of the automobile may be required to take it to a dealer for repairs before the power can be unlatched and the system returns to normal operation. To avoid an unnecessary and potentially large inconvenience to the owner, it is important that the safety disconnect circuit avoids false reports of a fault in order to avoid an unnecessary power disconnect and latch-off.

### SUMMARY

In a first example, a safety disconnect circuit includes a logic circuit having first, second and third logic inputs and a logic output. A latch has a latch input, a latch power input, and a latch output. The latch input is coupled to the logic output. A counter has a counter input and a counter output, wherein the counter input is coupled to the logic output. A switch is coupled between a fault terminal and a ground terminal, and has a switch control terminal. the switch control terminal is coupled to the latch output.

A first voltage supply has a first supply input and a first supply output. A second voltage supply has a second supply input and a second supply output. A multiplexer has first and second multiplexer inputs, a multiplexer control terminal, and a multiplexer output. The first multiplexer input is coupled to the first supply output. The second multiplexer input is coupled to the second supply output. The multiplexer output is coupled to the latch power input, and the multiplexer control terminal is coupled to the counter output.

In a second example, a safety disconnect circuit includes a latch having a latch input, a latch power input, and a latch output. The latch input is coupled to a validation terminal. A counter has a counter input, a counter supply terminal and a counter output. The counter input is coupled to the validation terminal. A first switch is coupled between a fault terminal and a ground terminal, and has a first switch control terminal. The first switch control terminal is coupled to the latch output.

A second switch is coupled between a first voltage supply terminal and the latch power input, and has a second switch control terminal. The second switch control terminal is coupled to the counter output. A third switch is coupled between a second voltage supply terminal and the latch power input, and has a third switch control terminal. The third switch control terminal is coupled to the counter output.

### BRIEF DESCRIPTION OF THE DRAWINGS

FIG. 1 shows a block diagram for an example safety disconnect circuit with automatic retry following an initial failure.

FIG. 2 shows a schematic diagram for an example circuit for toggling the enable terminal of a safety disconnect circuit in response to the nFAULT signal.

FIG. 3 shows a schematic diagram for an example safety disconnect circuit wherein the enable terminal is toggled in response to the nFAULT signal.

### DETAILED DESCRIPTION

In this description, the same reference numbers depict same or similar (by function and/or structure) features. The drawings are not necessarily drawn to scale.

In DC-DC converters, a circuit failure can lead to a condition where the output voltage or the output current is outside of an acceptable range, or a temperature rise that can affect the safety of the end user or the equipment. Numerous standards have been developed to address the required safety levels for different types of end equipment. In many cases, these safety standards require the system to detect and respond appropriately to failures within a particular amount of time.

For example, in the case of a DC-DC buck voltage converter, the failure of a pass switch (e.g. high-side switch) or a voltage feedback terminal that is shorted to ground can cause the entire input voltage to be passed to the output voltage terminal of the device. In many cases, this may cause damage to the downstream electronics that can lead to catastrophic failures in the system. In order to prevent such catastrophic failures, a separate battery voltage compliant external supervisor may be used to detect an overvoltage at the output voltage terminal, and respond by disconnecting the input voltage source that is providing power to the DC-DC buck voltage converter and/or the output voltage terminal that is providing power to downstream electronics.

However, this circuitry can add significant cost due to the additional components that may be required to implement the power-down circuitry. Furthermore, the additional circuitry can significantly increase the quiescent current drawn in the system, which is an undesirable outcome. In an automotive application, increasing the system quiescent current can drain the battery more quickly while the automobile is idle.

After the fault latch is set, the power-down condition remains in effect until the fault latch is reset. In some cases, resetting the fault latch may require returning the equipment to the manufacturer or a repair shop. It is possible for the power-down latch to be triggered by system noise and/or other transient conditions that may resolve themselves quickly and without intervention. However, a fully latched circuit would not be able to recover from the temporary and non-persistent or intermittent transient condition if the circuit has been powered down. This results in a false detection of a nonexistent fault leading to an unnecessary system power shutdown.

An important consideration is determining the proper criteria for the safety mechanism to trigger a system shut down. If the safety system triggers falsely, it can cause the system to react to a failure that does not actually exist, possibly causing a properly working system to be shut down unnecessarily. So, it may be advantageous to recheck the system following an initial failure report to verify that the failure is real, and that the failure is persistent and will not resolve on its own.

It is advantageous to have a safety disconnect circuit with a retry feature that allows the system to automatically retry following an initial failure. Power is removed from the system during the retry to prevent damage in case the fault is real. Retrying before declaring a permanent failure may help prevent the system from being put into a latched off state in response to a false trigger. Then, if the unsafe condition rectifies itself and the fault does not occur again during the retry, the system will continue with its normal operation.

In the case of an automotive application, this may prevent unnecessarily returning a car to a dealership or repair shop to clear the fault latch and turn the power back on in a situation where the automobile would have been safe to operate without any repairs. Automatically retrying up to a maximum number of retries allows the system to recover from an intermittent or non-persistent failure, and gives the system the opportunity to check multiple times to verify a fault before locking the system. This helps to ensure the safety system is not locking out power in response to an intermittent fault condition that clears itself while continuing to protect the system during the retries.

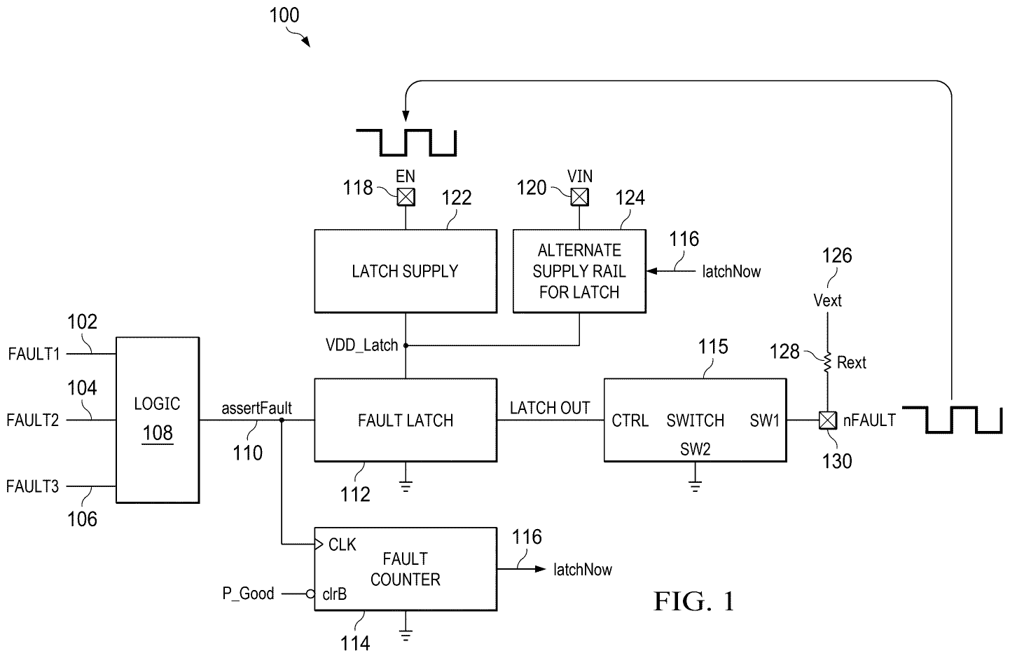

FIG. 1 shows a block diagram for an example safety disconnect circuit with automatic retry 100. Fault sensors (not shown) monitor particular system parameters such as voltages, currents, and temperatures. Each fault sensor provides a respective fault signal. A first fault signal, fault1 102, is provided to a first input of logic circuit 108. A second fault signal, fault2 104, is provided to a second input of logic circuit 108. A third fault signal, fault3 106, is provided to a third input of logic circuit 108. Logic circuit 108 may have more or less than three fault signals provided as respective inputs.

Logic circuit 108 provides a signal assertFault 110 at its output that is asserted if any of the fault signals fault1 102, fault2 104, or fault3 106 indicate a fault condition. Logic circuit 108 includes logic and timing circuits. Each of fault signals fault1 102, fault2 104, and fault3 106 are provided to an individual timing circuit specific to the type of fault sensor that is providing each respective input. For certain types of faults, the system may need to respond and validate the signal immediately with no delay. However, with other types of faults, a timing circuit may ensure that the fault remains for a period of time before validating the fault signal as indicating a legitimate fault. Each of the validated fault signals is then logically OR′ed together and provided as the signal assertFault 110.

The signal assertFault 110 is provided to an input of a latch, fault latch 112, and to the clock input of a counter, fault counter 114. The clear input of fault counter 114 receives a signal, P_Good, indicating whether the system power supply is operating within an acceptable voltage range. The output of fault counter 114 provides a signal latchNow 116. The output of fault latch 112 provides a signal LATCH OUT, and is coupled to the control terminal of switch 115. A first switch terminal of switch 115 is coupled to the nFAULT terminal 130. A second switch terminal of switch 115 is coupled to a ground terminal.

A resistor Rₑₓₜ 128 is coupled between the nFAULT terminal 130 and an external voltage source Vₑₓₜ 126. A first voltage source, latch supply 122, has an input coupled to enable terminal EN 118, and an output coupled to the supply terminal of fault latch 112. A second voltage source 124 has an input coupled to an input voltage terminal VIN 120, and an output coupled to the supply terminal of fault latch 112. Voltage source 124 has an enable terminal coupled to the output of fault counter 114 that receives the signal latchNow 116.

Safety disconnect circuit 100 automatically performs a retry following an initial fault reported by one or more of fault signals fault1 102, fault2 104, and fault3 106 by resetting fault latch 112. The failing safety parameter can then be retested and the fault latch 112 latches again if a safety parameter is still failing. This cycle will continue until the selected maximum number of retries is reached by the fault counter 114, at which time the fault counter 114 will issue a latchNow signal 116 at its output, and the system will remain latched out. The downstream electronics may then be disconnected from the circuit to prevent damage to them. The maximum number of automatic retries or retests allowed can be hardwired into fault counter 114 or be customizable according to the application. This improves the system robustness against noise and non-persistent or intermittent transient conditions.

Three safety monitors (not shown) may monitor different parameters of a DC-DC converter and generate fault signals fault1 102, fault2 104, and fault3 106. Fault signals fault1 102, fault2 104, and fault3 106 are inputs to logic circuit 108. Each fault signal is provided to a respective timing circuit within logic circuit 108 that is specific to the parameter being monitored. This helps ensure that the fault condition persists long enough before validating the fault.

If any of the fault signals results in a validated fault detection, the output of logic circuit 108 provides a signal, assertFault 110, to the input of fault latch 112 and to the clock input of fault counter 114, which then increments its count by one. Fault latch 112 is powered from the enable path originating from the enable terminal EN 118 for as long as the maximum count for fault counter 114 has not been reached. However, after the maximum count has been reached in fault counter 114, fault latch 112 will be powered by an alternate supply, voltage source 124.

Once the maximum count is reached in fault counter 114, the signal latchNow 116 is asserted, turning on voltage source 124 and turning off latch supply 122. In at least one case, the maximum fault count is set at four. However, the maximum fault count can instead be set to any positive integer less than or greater than four, and may be selectable based on the particular application.

Setting fault latch 112 asserts the signal LATCH OUT, which turn on switch 115. In at least one example, switch 115 is a field effect transistor (FET) in which the gate is coupled to the output of fault latch 112, the source is coupled to the ground terminal, and the drain is coupled to the nFAULT terminal 130. Turning on switch 115 brings the voltage at the nFAULT terminal 130 down to ground. When switch 115 is turned off, the nFAULT terminal 130 is pulled up by the external voltage source Vₑₓₜ 126 through resistor Rₑₓₜ 128.

To initiate a retry following a validated fault, the signal at the nFAULT terminal 130 goes low, triggering the enable of latch supply 122 through the enable terminal EN 118. This is an indication to the system that a fault was observed in the system and, in some cases, power to the rest of the system may be shut down to avoid damage to downstream electronics. Toggling the enable terminal EN 118 clears the fault latch 112.

Clearing fault latch 112 triggers the voltage converter to restart and commences a retest to determine whether the previous fault is still present. In many cases, power to the rest of the system remains turned off during the retests to protect the downstream electronics. If the safety fault is no longer detected, the system resumes operation. If the safety fault occurs again and a fault is observed, the fault counter 114 increases by one. This cycle of automatic retries continues until the maximum allowed faults have occurred.

Once the maximum allowed fault count is reached, the latch supply 122 is disabled and voltage source 124 is enabled by the latchNow signal 116. When this occurs, the voltage supply for fault latch 112 switches from the enable terminal EN 118 to input voltage terminal VIN 120, permanently latching the fault state. Toggling the enable terminal EN 118 will no longer clear the fault latch 112 when it is permanently latched. When this occurs, fault latch 112 can only be cleared by toggling the voltage at input voltage terminal VIN 120, which also clears the fault counter 114. Toggling the voltage at input voltage terminal VIN 120 requires removing the power supply from input voltage terminal VIN 120, then restoring the power supply to input voltage terminal VIN 120.

The automatic retry functionality of safety disconnect circuit 100 is enabled by toggling the dual power path to the fault latch 112 made up of latch supply 122 and voltage source 124. In at least one implementation, the enable terminal EN 118 is controlled as a function of the signal at the nFAULT terminal 130 by external circuitry at the system level. In another implementation, the enable terminal EN 118 is controlled as a function of the signal at the nFAULT terminal 130 by an internal circuit within the voltage converter IC.

Toggling the enable terminal EN 118 clears the fault latch 112 as long as the maximum number of retries has not yet been reached. After the fault counter 114 reaches the maximum limit of retries, the voltage supply for fault latch 112 is switched to the always-on supply rail from input voltage terminal VIN 120, and the latched state is permanently locked in. Power remains disconnected from downstream electronics in the system during the retries, and remains disconnected if the latched state becomes permanently locked in. Toggling power to input voltage terminal VIN 120 is required in order to clear the fault latch 112 after the fault latch has been permanently locked in. The supply source for fault latch 112, VDD_latch, is multiplexed between latch supply 122 and voltage source 124 providing a low quiescent current input. The signal latchNow 116 controls whether the supply source for fault latch 112, VDD_latch, comes from latch supply 122 or voltage source 124.

Safety disconnect circuit 100 controls the latching of fault latch 112 from the enable terminal EN 118, which can be connected to a Control Area Network (CAN) bus and may receive its signal from a microcontroller via the CAN bus. This allows that function to be combined with other microcontroller controls. In some cases, the external voltage source Vₑₓₜ 126 is derived from an automobile battery voltage, so the voltage at the nFAULT terminal 130 can go as high as the battery voltage, which may be 15V, 24V, or 65V in some cases. The high voltage nature of the nFAULT terminal 130 allows it to operate in the same voltage domain as the battery voltage and the enable terminal EN 118.

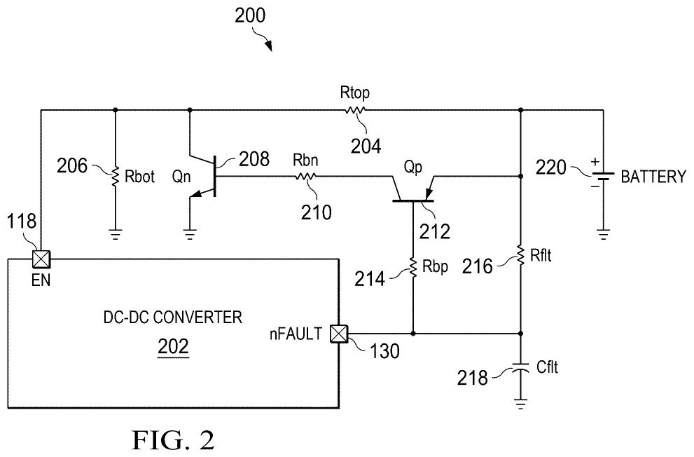

FIG. 2 shows a schematic diagram for an example circuit 200 for toggling the enable terminal of a safety disconnect circuit in response to the nFAULT signal. Voltage converter 202 has an enable terminal EN 118 and an nFAULT terminal 130. Resistor 206 is coupled between the nFAULT terminal 130 and a ground terminal. Switch Qₙ 208 is coupled between the enable terminal EN 118 and switch Qₙ 208. In at least one example, switch Qₙ 208 is a npn bipolar transistor. Resistor 204 is coupled between the enable terminal EN 118 and the positive terminal of a battery 220. The negative terminal of battery 220 is coupled to the ground terminal. Battery 220 may be replaced with a different type of DC voltage source.

Resistor 210 has a first terminal coupled to the control terminal of switch Qₙ 208. Switch Qₚ 212 is coupled between a second terminal of resistor 210 and the positive terminal of battery 220. In at least one example, switch Qₚ 212 is a pnp bipolar transistor. Resistor 214 is coupled between the control terminal of switch Qₚ 212 and the nFAULT terminal 130. Resistor R_{flt} 216 is coupled between the positive terminal of battery 220 and the nFAULT terminal 130. Capacitor C_{flt} 218 is coupled between the nFAULT terminal 130 and the ground terminal.

If a fault is detected and validated in the system, the nFAULT terminal 130 transitions from a logic high to a logic low. The nFAULT terminal 130 transitioning low pulls the voltage at the control terminal of switch Qₚ 212 low and turns on switch Qₚ 212. Turning on switch Qₚ 212 pulls the control terminal of switch Qₙ 208 high, and switch Qₙ 208 is turned on. Turning on switch Qₙ 208 pulls the voltage at the enable terminal EN 118 low, disabling voltage converter 202. The timing of this is set by the resistance of resistor R_{flt} 216 and the capacitance of capacitor C_{flt} 218, which determines the duration that the nFAULT terminal 130 remains low, and the duration that the enable terminal EN 118 remains low.

In response to the enable terminal EN 118 transitioning low, the voltage converter 202 clears, which causes the nFAULT terminal 130 to release and transition high. The voltage at the nFAULT terminal 130 is then pulled back up to the battery voltage with a time constant that is determined by the resistance of resistor R_{flt} 216 and the capacitance of capacitor C_{flt} 218. This is merely one example implementation of a circuit for toggling the enable terminal EN 118 as a function of the nFAULT terminal 130, and other implementations for performing the same function are also contemplated.

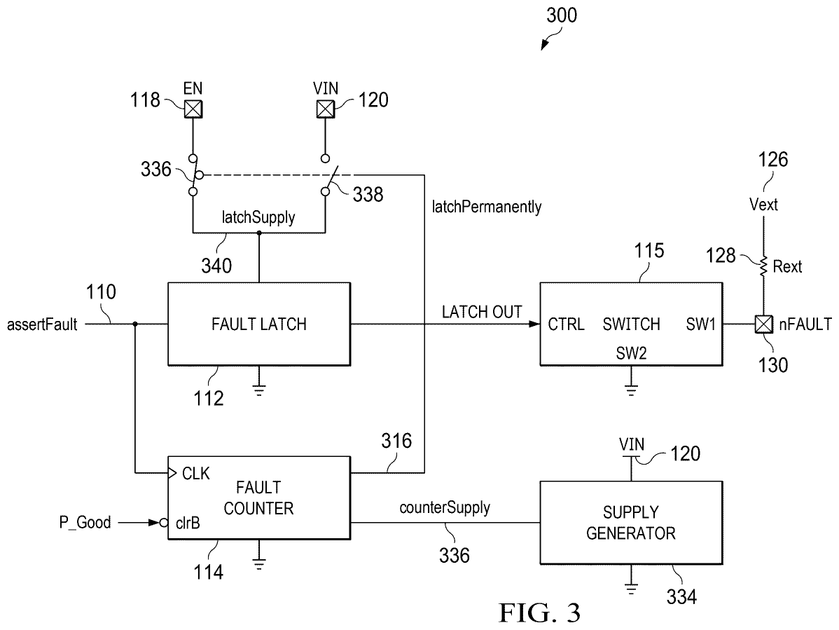

FIG. 3 shows a schematic diagram for an example safety disconnect circuit 300 wherein the enable terminal EN 118 toggles in response to the signal at the nFAULT terminal 130. Fault sensors (not shown) monitor particular parameters such as voltages, currents, and temperatures. Each fault sensor provides a respective fault signal that must be validated to ensure that the fault is not due merely to a transient condition. The validation of the faults can occur in a logic circuit (not shown) that includes logic and timing circuitry. The logic circuit (not shown) provides a signal assertFault 110 at its output that is asserted if any validated fault signal indicates a fault condition in the system.

The signal assertFault 110 is provided to an input of fault latch 112, and to the clock input of fault counter 114. The clear input of fault counter 114 receives a signal, P_Good, indicating whether the system power supply is operating within an acceptable voltage range. The output of fault counter 114 provides a signal latchPermanently 316. Fault latch 112 has a power terminal coupled to the latchSupply terminal 340. The output of fault latch 112 provides a signal LATCH OUT, and is coupled to the control terminal of switch 115.

A supply generator 334 has an input coupled to the input voltage terminal VIN 120, and has an output, counterSupply 336, coupled to the supply terminal of fault counter 114. In at least one example, supply generator is a buck voltage regulator. The voltage at the input voltage terminal may be as high as 65V, which would be harmful to provide to fault counter 114. So, supply generator 334 takes a higher voltage from the input voltage terminal VIN 120 and brings it down to a lower voltage. A first switch terminal of switch 115 is coupled to the nFAULT terminal 130. A second switch terminal of switch 115 is coupled to a ground terminal. A resistor Rₑₓₜ 128 is coupled between the nFAULT terminal 130 and an external voltage source Vₑₓₜ 126.

Switch 336 is coupled between the enable terminal EN 118 and the latchSupply terminal 340. Switch 338 is coupled between the input voltage terminal VIN 120 and the latch Supply terminal 340. The control terminals of switch 336 and switch 338 are each coupled to the output of fault counter 114 and receive the signal latchPermanently 316. The control terminal of switch 336 has an opposite logic from the control terminal of switch 338 so that only one of switch 336 and 338 may be closed at a time, but not both. Switches 336 and 338 operate as a multiplexer to choose the voltage source for the latchSupply terminal 340 from either the enable terminal EN 118 or the input voltage terminal VIN 120.

Whenever a fault sensor determines that a safety limit has been violated, a fault signal is generated. If a fault signal is validated, then the signal assertFAULT 110 transitions from low to high and advances a count in the fault counter 114 by one. The signal assertFAULT 110 transitioning high also sets the fault latch 112, causing the LATCH OUT signal to go high. Switch 115 turns on in response to the LATCH OUT signal transitioning high, causing the nFAULT terminal 130 to be connected to ground.

As long as the fault counter 114 does not reach the particular limit set for maximum number of retries following an initial failure, the signal latchPermanently 316 remains low. As long as the signal latchPermanently remains low, switch 336 is closed and switch 338 is open. So, the latchSupply terminal 340 is coupled to the enable terminal EN 118 until the signal latchPermanently 316 goes high because switches 336 and 338 are multiplexing between the enable terminal EN 118 and the input voltage terminal VIN 120, and the enable terminal EN 118 is currently the selected input.

If the maximum fault count is reached by fault counter 114, then the signal latchPermanently transitions from low to high, which opens switch 336 and closes switch 338, flipping the multiplexer output. Closing switch 338 shorts the latchSupply terminal 340 to the input voltage terminal VIN 120. The supply terminal of fault latch 112 is no longer being supplied by the enable terminal EN 118, but is now being supplied by the input voltage terminal VIN 120.

After this occurs, any further toggling of the enable terminal EN 118 cannot clear the fault latch 112. In this case, the fault latch 112 can now only be cleared by removing power to input voltage terminal VIN 120, which in some cases is at the battery voltage. In this case, the battery would have to be disconnected from the system to reset the fault latch. Disconnecting the battery from the system requires substantially more than sending a reset signal from a microcontroller to the device through the CAN bus to reset fault latch 112 as can be done following a fault as long as the maximum fault count has not yet reached by fault counter 114.

Prior to reaching the maximum fault count in fault counter 114, toggling the signal at the enable terminal EN 118 clears fault latch 112 because the power supply for fault latch 112 is coming from the enable terminal EN 118. Clearing the fault latch 112 allows the converter to restart, and allows a retest. However, this does not clear fault counter 114, so fault counter 114 continues to increment by one each time this occurs. Removing power from the input voltage terminal VIN 120 then reapplying power resets fault latch 112 and resets fault counter 114.

In this description, “terminal,” “node,” “interconnection,” “lead” and “pin” are used interchangeably. Unless specifically stated to the contrary, these terms generally mean an interconnection between or a terminus of a device element, a circuit element, an integrated circuit, a device, or other electronics or semiconductor component.

In this description, “ground” includes a chassis ground, an Earth ground, a floating ground, a virtual ground, a digital ground, a common ground and/or any other form of ground connection applicable to, or suitable for, the teachings of this description.

In this description, the term “couple” may cover connections, communications or signal paths that enable a functional relationship consistent with this description. For example, if device A generates a signal to control device B to perform an action, then: (a) in a first example, device A is coupled to device B by direct connection; or (b) in a second example, device A is coupled to device B through intervening component C if intervening component C does not alter the functional relationship between device A and device B, so device B is controlled by device A via the control signal generated by device A.

In this description, even if operations are described in a particular order, some operations may be optional, and the operations are not necessarily required to be performed in that particular order to achieve specified results. In some examples, multitasking and parallel processing may be advantageous. Moreover, a separation of various system components in the embodiments described above does not necessarily require such separation in all embodiments.

Modifications are possible in the described embodiments, and other embodiments are possible, within the scope of the claims.

What is claimed is:

1. A safety disconnect circuit, comprising:
a logic circuit having first, second and third logic inputs and a logic output;
a latch having a latch input, a latch power input, and a latch output, wherein the latch input is coupled to the logic output;
a counter having a counter input and a counter output, wherein the counter input is coupled to the logic output;
a switch coupled between a fault terminal and a ground terminal and having a switch control terminal, wherein the switch control terminal is coupled to the latch output;
a first voltage supply having a first supply input and a first supply output;
a second voltage supply having a second supply input and a second supply output; and
a multiplexer having first and second multiplexer inputs, a multiplexer control terminal, and a multiplexer output, wherein the first multiplexer input is coupled to the first supply output, the second multiplexer input is coupled to the second supply output, the multiplexer output is coupled to the latch power input, and the multiplexer control terminal is coupled to the counter output.

2. The safety disconnect circuit of claim 1, wherein the first supply output provides a lower voltage to the latch power input if the first supply output is selected by the multiplexer, and the second supply output provides a higher voltage to the latch power input if the second supply output is selected by the multiplexer.

3. The safety disconnect circuit of claim 2, wherein the multiplexer selects the first supply output if a count of the counter has not reached a maximum count value, and selects the second supply output if the count has reached the maximum count value.

4. The safety disconnect circuit of claim 3, wherein toggling the first supply output resets the latch if the count has not reached a maximum count value, and does not reset the latch if the count has reached the maximum count value.

5. The safety disconnect circuit of claim 4, wherein toggling the second supply output resets the latch and resets the count to zero.

6. The safety disconnect circuit of claim 1, further comprising an external voltage supply coupled to the fault terminal through a resistor.

7. The safety disconnect circuit of claim 3, wherein the second supply input is coupled to an automobile battery.

8. The safety disconnect circuit of claim 1, wherein each of the first, second and third logic inputs are provided by a respective fault detection circuit.

9. The safety disconnect circuit of claim 8, wherein the logic circuit includes timing circuits, and each of the first, second and third logic inputs are coupled to a respective timing circuit.

10. The safety disconnect circuit of claim 1, wherein the first voltage supply is controlled by a signal provided at the fault terminal.

11. A safety disconnect circuit, comprising:
a latch having a latch input, a latch power input, and a latch output, wherein the latch input is coupled to a validation terminal;
a counter having a counter input, a counter supply terminal and a counter output, wherein the counter input is coupled to the validation terminal;
a first switch coupled between a fault terminal and a ground terminal and having a first switch control terminal, wherein the first switch control terminal is coupled to the latch output;
a second switch coupled between a first voltage supply terminal and the latch power input, and having a second switch control terminal, wherein the second switch control terminal is coupled to the counter output; and
a third switch coupled between a second voltage supply terminal and the latch power input, and having a third switch control terminal, wherein the third switch control terminal is coupled to the counter output.

12. The safety disconnect circuit of claim 11, wherein the first voltage supply terminal provides a lower voltage than the second voltage supply terminal, and the second voltage supply terminal is coupled to an automobile battery.

13. The safety disconnect circuit of claim 11, wherein the second switch is closed and the third switch is open responsive to a count of the counter not having reached a maximum count value, and the second switch is open and the third switch is closed responsive to the count having reached the maximum count value.

14. The safety disconnect circuit of claim 13, wherein toggling power provided to the first voltage supply terminal resets the latch if the count has not reached a maximum count value, and does not reset the latch if the count has reached the maximum count value.

15. The safety disconnect circuit of claim 14, wherein toggling power provided to the second voltage supply terminal resets the latch and resets the count to zero.

16. The safety disconnect circuit of claim 11, further comprising an external voltage supply coupled to the fault terminal through a resistor.

17. The safety disconnect circuit of claim 11, wherein the second voltage supply terminal is coupled to an automobile battery.

18. The safety disconnect circuit of claim 11, wherein a signal provided at the validation terminal indicates a system fault has been detected.

19. The safety disconnect circuit of claim 11, further comprising a voltage regulator having a regulator input and a regulator output, wherein the regulator input is coupled to the second voltage supply terminal, and the regulator output is coupled to the counter supply terminal.

20. The safety disconnect circuit of claim 11, wherein a voltage at the first voltage supply terminal is controlled by a signal provided at the fault terminal.
